(19) United States
(12) Patent Application Publication
(10) Pub. No.: US 2024/0222239 A1
(43) Pub. Date: Jul. 4, 2024

(54) SEMICONDUCTOR ELEMENT WITH BONDING LAYER HAVING FUNCTIONAL AND NON-FUNCTIONAL CONDUCTIVE PADS

(71) Applicant: ADEIA SEMICONDUCTOR BONDING TECHNOLOGIES INC., San Jose, CA (US)

(72) Inventors: Guilian Gao, San Jose, CA (US); Gaius Gillman Fountain, JR., Youngsville, NC (US)

(21) Appl. No.: 18/395,265

(22) Filed: Dec. 22, 2023

Related U.S. Application Data
(60) Provisional application No. 63/477,551, filed on Dec. 28, 2022.

(51) Int. Cl. H01L 23/498; H01L 23/00

(52) U.S. Cl. CPC H01L 23/49811; H01L 24/05; H01L 2224/05008; H01L 2224/05147; H01L 2224/08147; H01L 2924/14

(57) ABSTRACT

A semiconductor element having an interconnect bonding layer with functional and non-functional metal contact pads therein surrounded by a dielectric material is disclosed. The functional metal contact pads are exposed to the bonding surface and are connected to a buried metal layer. The non-functional metal contact pads are distributed in the regions having no or less functional metal contact pads, and are exposed to the bonding surface and terminated at a partial depth of the functional metal pads. Each of the functional and non-functional metal contact pads is formed involving a one etching step single damascene process.

### PRIORITY CLAIM

This application claims the benefit under 35 U.S.C. § 119(e)(1) of U.S. Provisional Application No. 63/477,551, filed Dec. 28, 2022, the entire content of which is hereby incorporated by reference in its entirety.

### BACKGROUND

### Field

The field relates to microelectronics with functional and non-functional conductive (e.g., metal) pads in a bonding layer.

### Description of the Related Art

The semiconductor industry has experienced tremendous growth over the past several decades as engineers have developed chips with ever smaller transistors integrated thereon, as correctly predicted by Moore's Law. However, the industry is aware that the effort to reduce transistor size on silicon chips is approaching a physical limit. Meanwhile, consumer electronics, including computers and smart phones, continue to grow more and more complex, requiring effective utilization of a large numbers of transistors. One approach to improve three-dimensional (3D) integration is to stack chips or wafers on top of each other to form a 3D integrated structure. Direct hybrid bonding enables higher density interconnects between stacked elements. However, direct bonding between semiconductor elements utilizes planarized bonding surfaces with tight flatness tolerance which may create challenges.

### BRIEF DESCRIPTION OF THE DRAWINGS

Specific implementations will now be described with reference to the following drawings, which are provided by way of example, and not limitation.

FIG. 1 is a schematic cross-sectional view of a semiconductor element having at least one functional metal pad and at least one dummy metal pad embedded in a bonding layer, with the at least one functional metal pad being formed by a dual damascene process.

FIG. 2 is a schematic cross-sectional view of an embodiment showing a semiconductor element having at least one functional metal pad and at least one dummy metal pad embedded in a bonding layer, with each of the at least one functional metal pad and the at least one dummy metal pad being formed by a single damascene process.

FIG. 3 is a schematic cross-sectional view of another embodiment of the disclosure showing a semiconductor element having at least one functional metal pad and at least one dummy metal pad embedded in a bonding layer, with each of the at least one functional metal pad and the at least one dummy metal pad being formed by a single damascene process.

FIG. 4-FIG. 10 are schematic cross-sectional views illustrating example processes to fabricate the functional and dummy metal pads embedded in a bonding layer shown in FIG. 3.

FIG. 11A and FIG. 11B are schematic cross-sectional views illustrating example conductive pads fabricated by adopting a dual damascene process.

FIG. 11C and FIG. 11D are schematic cross-sectional views illustrating example conductive pads fabricated by adopting a single damascene process according to various embodiments disclosed herein.

FIG. 12-FIG. 13 are schematic cross-sectional views illustrating example processes to fabricate the functional and dummy metal pads embedded in a bonding layer shown in FIG. 2.

FIG. 14 is a schematic cross-sectional view of two microelectronic elements configured to be bonded together.

FIG. 15 is a schematic cross-sectional view of bonded structure comprising the two microelectronic elements in FIG. 14 bonded together.

### DETAILED DESCRIPTION

When a bonding layer is formed over a semiconductor element, conductive contact pads are embedded in a nonconductive (e.g., dielectric) layer. A chemical mechanical processing (CMP) is performed to remove extra material on the dielectric layer to planarize the surface. The semiconductor can be prepared to be directly bonded to another semiconductor element or device without an intervening adhesive. Due to thermal expansion mismatch between the metal and the dielectric materials that are used, the thin film processes may result in stress in the bonding layer, e.g., the metal traces under tension and the dielectric material under compression. This stress can cause deformation and/or warpage in the semiconductor element, e.g., a device die or chip, a wafer, or a passive device. Therefore, there is a continuing need to reduce stresses in bonding layers and distortion in semiconductor elements.

To reduce the stress and distortion in the bonding layer due to the metal and dielectric material thermal expansion mismatch, in various embodiments, electrically non-functional (or dummy) metal pads can be embedded in the non-conductive dielectric material of the bonding layer to the regions that have no or fewer functional metal pads. This can be done in a way that the distribution of metal pads in dielectric material, including functional and non-functional, becomes more uniform. Thermal expansion mismatch between two mingled materials results in one material under tension and the other under compression. The thermal expansion coefficient of a metal, e.g., copper, is usually greater than the thermal expansion coefficient of a dielectric material, e.g., silicon oxide. Therefore, during a deposition or annealing process (or other process that uses elevated temperatures) when a semiconductor element cools down from an elevated temperature, the metal shrinks more than the dielectric material. Because the two materials are disposed side-by-side, the metal may be under tension and the dielectric material may be under compression. If the two materials are uniformly distributed with each other, however, the expansion of one material can be absorbed or counteracted by the contraction of the other. As such, the tensile and compressive stresses can be reduced or controlled. Therefore, uniform or approximately uniform distribution of metal pads in the dielectric material helps relieve the stress due to thermal expansion mismatch, and reduces distortion.

In various embodiments, the electrically non-functional or dummy metal pads in the interconnect or bonding layer may be shallower than the electrically functional or active pads. If the non-functional metal pads were to extend to a greater depth (e.g., to the same depth as the functional pads), then the dummy pads may short the metal traces buried in the interconnect layers below the dummy pad(s).

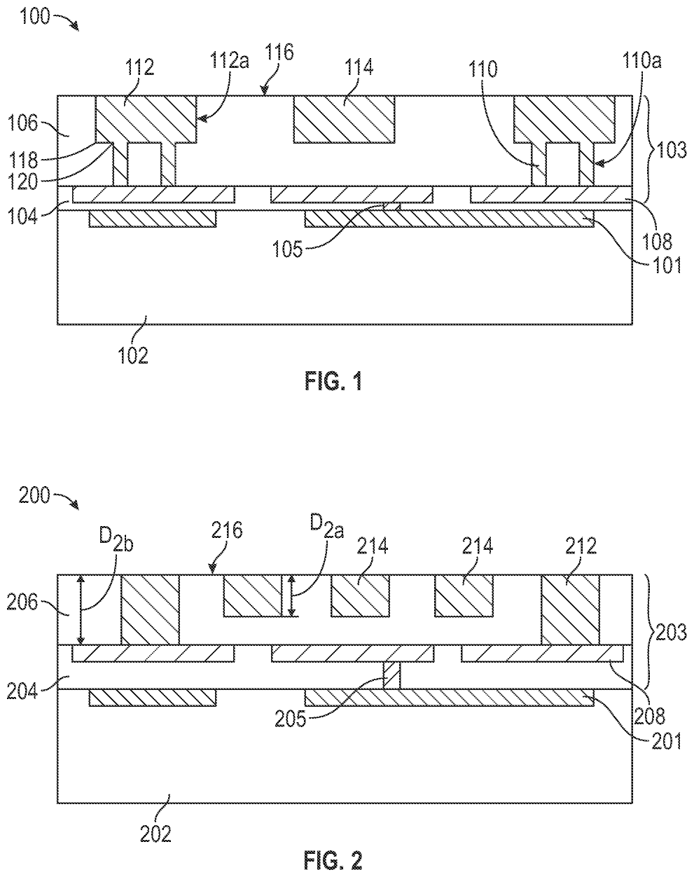

Conventionally, the functional metal pads in the dielectric layer may be formed by a dual damascene process. FIG. 1 shows a schematic cross-sectional view of a semiconductor element 100 having a device layer or device portion 102 and an interconnect structure 103 provided on the device layer 102 (also referred to as device portion herein). As explained herein, in various embodiments, the interconnect structure 103 can comprise a plurality of non-conductive layers (e.g., dielectric layers 104 and 106 in FIG. 1) deposited on the device layer 102. The second dielectric layer or bonding layer 106, which forms at least part of the interconnect structure 103, can be prepared to be bonded (e.g., directly hybrid bonded) to another element or device and can accordingly serve as a nonconductive bonding layer. The first and second dielectric layers 104, 106 can be formed of the same material or of different materials. Although the interconnect structure 103 includes two dielectric layers 104, 106, in other embodiments, more or fewer dielectric layers can be provided. A metal layer 108 is buried in the second dielectric layer 104, making connection to a circuitry 101 patterned or otherwise provided in the device layer 102 through a via 105 or other conductors (e.g., other traces and/or vias). A plurality of vias 110 make connections with the metal layer 108 (e.g., traces) at one end and make connections to functional metal pads 112 at the other end in the second dielectric layer 106. The plurality of vias 110 may be made of copper, tungsten, or polysilicon. The functional metal pad 112 can be exposed at the surface 116 of the dielectric material 106. Non-functional or dummy metal pads 114 are also exposed at the surface 116 of the dielectric material 106 and extend into the dielectric material 106 a partial depth and terminate before reaching the interconnect metal layer 108 underneath. The non-functional metal pads 114 are distributed in the regions that have no or fewer functional metal pads 112.

A dual damascene process can be used to form the functional metal pads 112 together with the vias 110 in the dielectric layer 106 in FIG. 1. The dual damascene process can be performed by a two-step etching method, e.g., a via first process to form narrower holes 110a in the second dielectric layer 106, followed by a trench formation process that forms trenches 112a that are wider than the holes. In the via first method the finer pitch, higher aspect ratio holes 110a extend through the second dielectric material 106, as shown in FIG. 1 as the holes for the vias 110. This process is usually more challenging than the subsequent trench formation process. The more expensive masks for patterning make the dual damascene process more complicated than the single damascene process. On the other hand, the trench process is used to form the metal contact pads with larger dimensions, as shown in FIG. 1, e.g., to form the electrically functional or active pads 112 and the electrically inactive or non-functional pads 114 (also referred to herein as dummy pads). Therefore, the trench formation process is normally simpler than the via formation process. Another drawback of utilizing the narrower via structure 110 is that it is usually accompanied by a higher electrical resistance due to its smaller cross-sectional dimensions.

One characteristic of the dual damascene process shown in FIG. 1 is that the functional contact pads 112 and the vias 110 have a two-step discontinuous sidewall structure, due to the two-step etching process. This is revealed by corners 118 and 120 between the functional pad 112 portion and the via 110 portion, as shown in FIG. 1. In real practice, these corners may not be as sharp as illustrated schematically in FIG. 1. But the stepped or cornered connection between the vias 110 and functional pad 112 is a sidewall discontinuity that makes the sidewalls jagged and/or non-unitary.

Therefore, there is a motivation to replace the relatively complex dual damascene process using expensive masks with a simpler fabrication process. A single damascene process can reduce processing costs and simply fabrication. FIG. 2 is a schematic cross-sectional view of an example embodiment of the disclosure. In FIG. 2, an interconnect structure or layer 203 is disposed on a microelectronic device layer or device portion 202. The interconnect structure 203 comprises a second non-conductive or dielectric layer 206, which forms or includes a bonding layer of a semiconductor element 200, and a first non-conductive or dielectric layer 204 having a conductive layer or underlying interconnect 208 buried therein. The conductive layer 208 may be an interconnect metal layer serves to further connect to an external device or element. The device layer 202 can comprise a semiconductor device portion patterned with devices (e.g., active circuitry 201 schematically illustrated in FIG. 2). In other embodiments, the device layer 202 can comprise a portion of an interposer or other electronic device with or without active devices therein. The device layer 202 may comprise a wafer, an integrated device die or chip, e.g., a complementary metal-oxide semiconductor (CMOS) chip, or a passive device, etc.

The conductive (e.g., metal) layer 208 can be buried or embedded in the dielectric layer 204 close to the device layer 202. In some embodiments, the interconnect metal layer 208 can be an outermost layer of the device layer 202, e.g., the metal layer 208 may be formed in a dielectric layer provided over a semiconductor portion of the device layer 202 in a back-end-of-line (BEOL) process. In some embodiments, the metal layer 208 can be a redistribution layer (RDL) provided before the second dielectric layer 206 is deposited. The metal layer 208 can electrically communicate with one or more devices in the device layer 202 in some embodiments, e.g., maybe electrically connected to the active circuitry 201 in the device layer 202 through a via 205. At least one functional or active metal pad 212 and at least one non-functional metal pads 214 can be partially embedded in the second dielectric layer 206. Whereas the functional or active metal pads 212 extend from a top surface 216 through at least a portion of the second dielectric layer 206 to connect to (e.g., to contact) the buried metal layer 208, the non-functional metal pads 214 extends from the top surface 216 and terminates at a location shallower than the functional metal pads 212. The metal contact pads 212, 214 may take different cross-sectional shapes and dimensions, e.g., width or diameter, as viewed in the top surface 216, e.g., square, triangular, round, polygon, and etc. of different sizes. In some embodiments, the functional metal pads 212 can have a same first shape with a same first dimension, and the non-functional metal pads 214 can have a same second shape with a same second dimension. In some embodiments, the functional metal and the non-functional metal pads 212, 214 can have the same shape with the same dimension. In other embodiments, the functional metal pads 212 and the non-functional metal pads 214 may have different shapes and/or different dimensions. As can be seen in FIG. 2, the depth D₂ₐ of the non-functional metal pads 214 is shallower than the depth D_{2b} of the functional metal pads 212. As such the non-functional pads 214 terminate above and do not contact or electrically connect to the buried metal layer 208. In this way, the non-functional metal pads 214 do not short the metal traces of the conductive metal layer 208. Accordingly, in various embodiments, non-functional pads 214 (and the functional pads 212) may be disposed vertically over the conductive metal layer 208, with the functional pads connected to the metal layer 208 and the non-functional pads 214 not connected to the metal layer 208.

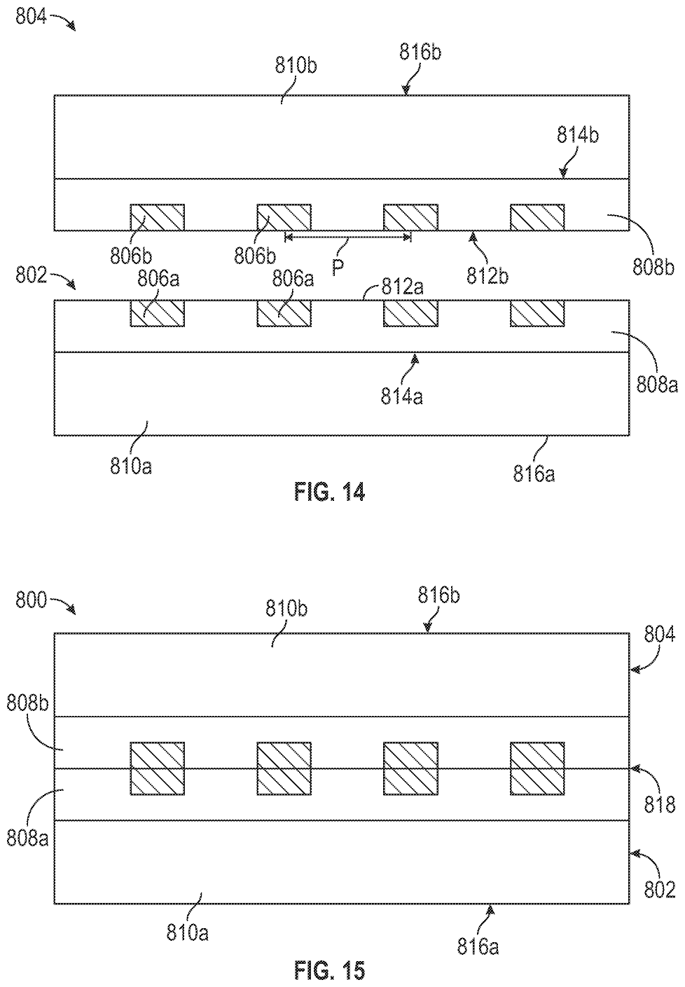

Accordingly, in various embodiments disclosed herein, the functional conductive pads 212 can electrically connect to an electrically functional component of the semiconductor element 200, such as a trace (e.g., buried metal layer 208) that in turn connects to a device (e.g., circuitry 201) or any other suitable electrically functional component (e.g., interconnects in an interposer, a passive device, or any other suitable functional component). The dummy or nonfunctional pads 214 may be electrically inactive such that the dummy or electrically nonfunctional pads 214 are electrically isolated within the semiconductor element 200 (e.g., the dummy pads 214 do not electrically connect to a functional component or circuit in the semiconductor element 200). As explained herein in connection with FIGS. 14-15, the functional pads 212 and the nonfunctional pads 214 can be directly bonded to opposing conductive features (e.g., opposing pads or opposing exposed through vias) on a second semiconductor element (see FIGS. 14-15). In some embodiments, the functional pads 212 can be directly bonded to opposing functional pads. In some embodiments, in particular function of the functional pads is deactivated, the functional pads 212 may be directly bonded to opposing nonfunctional pads. In some embodiments, the nonfunctional or dummy pads 214 can be directly bonded to opposing nonfunctional or dummy pads. In some embodiments, the nonfunctional or dummy pads 214 can be directly bonded to opposing functional pads if particular function of the opposing functional pads is deactivated.

As compared to the structure of semiconductor element 100 in FIG. 1, the functional or active metal pads 212 and the non-functional metal pads 214 can be formed by a single damascene process. As such, the functional metal pads 212 may have no separate or distinct via portions and can be characterized by a continuous or unitary sidewall. The sidewalls of the functional metal pads 212 may form an angle with a vertical reference line due to an etching process, but the angle may be small. The sidewalls of the illustrated embodiments do not have abrupt discontinuities or corners, such as corners 118 and 120 in FIG. 1 formed by the dual damascene process. An important advantage of the single damascene process in producing the functional metal pads 212 in FIG. 2 is that it is simpler than the dual damascene process in producing the functional metal pads 112 and the connected vias 110 in FIG. 1. This is because that producing the functional metal pads 212 in FIG. 2 does not utilize the more expensive or more complex masking used with the structure in FIG. 1. Another advantage of the functional metal pads 212 in FIG. 2 is the lower electrical resistance from the thicker cross-sectional dimensions of the metal pads and, thus better performance of the semiconductor element 200 compared to the performance of the semiconductor 100 of FIG. 1. Moreover, the thickness D_{2b} for bonding contact pads 212 (and the thickness D₂ₐ for the dummy pads 214) in FIG. 2 can be formed thicker than the contact pads 112 in FIG. 1, because contact pads 212 are not connected to underlying vias and extend through the thickness of the bonding layer 206. Meanwhile, the thickness of the bonding layer 216 in FIG. 2, which is the same as the thickness D_{2b} of the contact pads 212, can be formed thinner than the bonding layer 106 in FIG. 1 for the same reason: the bonding layer 106 can be formed thick enough to embed both the contact pads 112 and the underlying vias 110. The thinner bonding layer 206 and thicker contact pads 212 as described above can ensure that the stress in the second dielectric layer or bonding layer 206, which may result in distortion and warpage in the semiconductor element 200, can be reduced and better controlled compared with the situation in FIG. 1. Due to the thicker pads 212, the annealing process of the hybrid direct bonding for the device of FIG. 2 can then be performed at lower temperature annealing as compared to the process used to form the device of FIG. 1. With the stress in the second dielectric layer 206 reduced, the warpage in the semiconductor element is reduced, which may result in reduced risk for void formation at the bonding interface improved direct bonding quality.

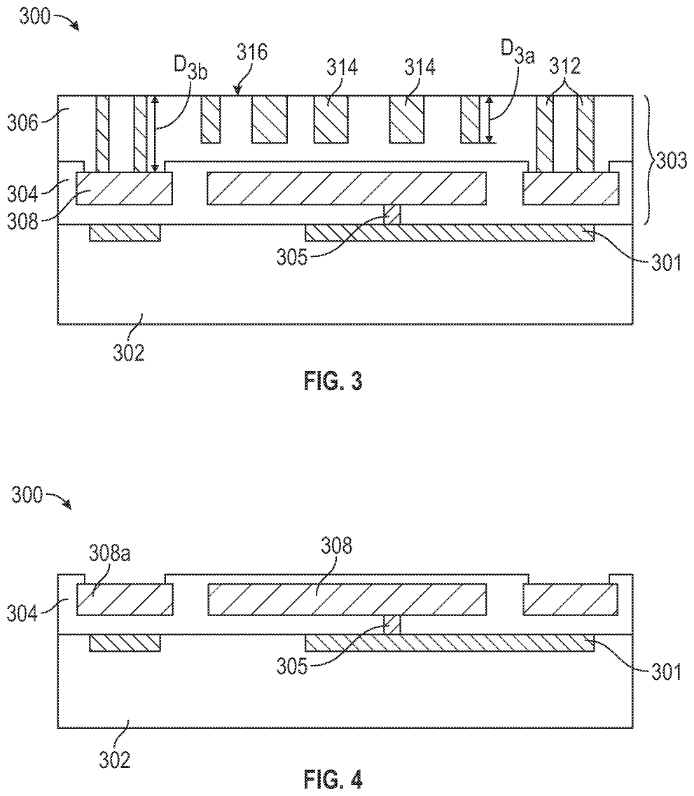

Another example embodiment of the disclosure using a single damascene process to build functional and non-functional metal pads in a bonding layer is depicted in FIG. 3. In FIG. 3, a schematic cross-sectional view of a semiconductor element 300 is shown to include a device layer or device portion 302 and a first dielectric layer 304 disposed on the device layer 302. An interconnect conductive layer or underlying interconnect 308 is embedded in the first dielectric layer 304. A second nonconductive or dielectric layer or bonding layer 306 can be deposited on the first nonconductive or dielectric layer 304. The second dielectric layer 306 and conductive pads 312 and 314 can serve as a bonding structure of the semiconductor element 300. Functional or active metal pads 312 extend from a top surface 316 through the second dielectric layer 306 and make connections with the interconnect conductive or metal layer 308 buried in the first dielectric layer 304. Like the semiconductor element 200 shown in FIG. 2, non-functional or dummy metal pads 314 extend from the top surface 316 through the second dielectric layer 306 but terminate in the second dielectric layer 306 above the buried conductive layer 308. Both the functional and non-functional conductive pads 312 and 314 can be made of the same material as the buried metal layer 308. Alternatively, the pads 312, 314 can be made of a different material. For example, in some embodiments, the buried conductive layer 308 can comprise aluminum, and the pads 312, 314 can comprise copper, or vice versa. As described with respect to element 200 of FIG. 2, the pads 312, 314 can have different arrangements of shapes and dimensions as viewed in the top surface 316, e.g., square, triangular, round, polygon, and etc. of various dimensions. For example, in same embodiments, the active metal pads 312 can have one shape with one dimension, and the dummy metal pads 314 can have another shape with another dimension. In some embodiments, the active metal pads 312 and the dummy metal pads 314 can have various shapes with various dimensions. As can be seen in FIG. 3, the depth D₃ₐ of the dummy metal pads 314 is shallower than the depth D_{3b} of the active metal pads 212. Also, as with the semiconductor element 200 in FIG. 2, the active metal pads 312 and 314 can be formed by a single damascene processes, which may be simpler than the processes used to form the semiconductor element 100 in FIG. 1.

As compared with FIG. 2, more than one functional contact pad 312 can be formed to connect to each buried metal trace 308. Each of the multiple contact pads 312 may be thinner than the single contact pad 212 connecting to each buried metal trace 208 in FIG. 2. However, such redundance may improve quality and reliability of the functional contact pads 312. As shown in FIG. 3, dummy pads 314 can have different width, contrasting with the uniform width of dummy pads 214 in FIG. 2. The width of each dummy pad 314 may be related to the density of the functional pads 312 in its surrounding. The placement and the different widths of the metal pads 312 and 314 can make the distribution of the metal pads 312 and 314 in the second dielectric layer 306 approximately uniform in some embodiments, so that stress in the dielectric layer 306 is minimized, as explained with FIG. 2. Reducing stress in the interconnect structure or layer 303 can reduce warpage of the dielectric layer 306 and the semiconductor 300.

FIGS. 4-10 are schematic cross-sectional views illustrating a method for forming the semiconductor element 300 in FIG. 3. In FIG. 4, the device layer 302 of the semiconductor element 300 can comprise a carrier or a substrate, e.g., a die, a wafer, an interposer, etc. The device layer 302 may have the circuitry 301 disposed therein, and is covered by the first dielectric layer 304. The conductive (e.g., metal) layer 308 is embedded in the first dielectric layer 304, making connection with the circuitry 301 in the device layer 302 through a via 305. The embedded metal layer 308 may be covered by a nonconductive layer (e.g., a portion of dielectric layer 304 or another dielectric layer disposed over layer 304, such as a passivation layer). The nonconductive layer (e.g., a portion of layer 304) can be etched to expose a metal trace 308a connected to a device or the circuitry 301 in the device layer 302. In other embodiments, the trace 308a can be part of an interposer and may not be directly connected to a device. In some embodiments, the first dielectric layer 304 and the metal layer 308 may be fabricated as part of a microelectronic device fabrication, e.g., wafer fabrication. In this case a passivation layer may be coated over the wafter surface for protection and only allowing the certain metal traces exposed to make external connections. The semiconductor element 300 in FIG. 4, including the device layer 302 and the first dielectric layer 304 with embedded metal 308 may comprise a complementary metal-oxide semiconductor (CMOS) device.

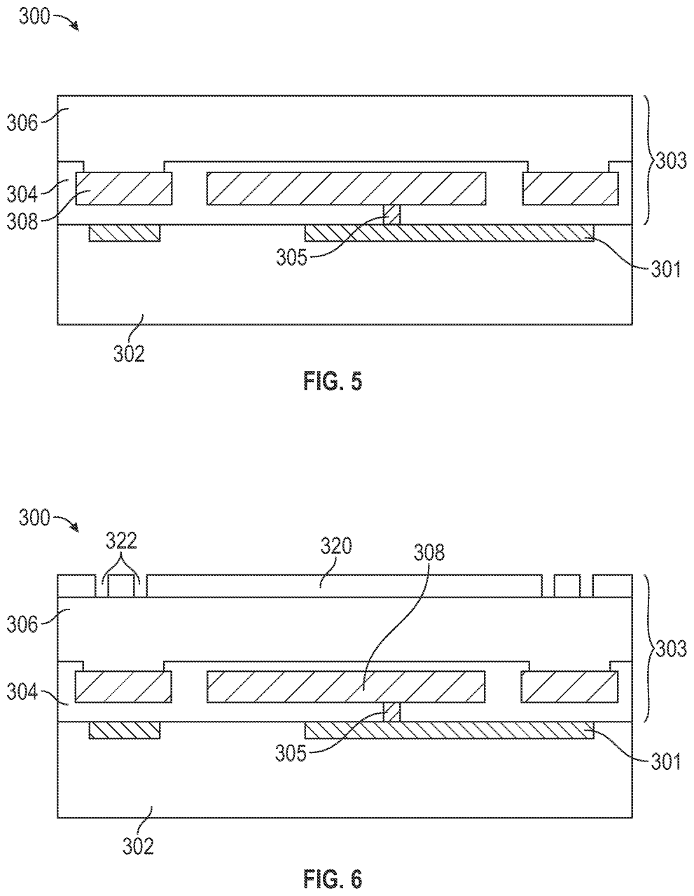

As shown in FIG. 5, the second dielectric layer 306 (which can serve as a portion of a bonding layer) can be deposited over the top surface of the semiconductor element 300 shown in FIG. 4, covering the first dielectric material 304 and the exposed metal traces 308a. The second dielectric layer 306 can comprise an inorganic dielectric, such as silicon oxide, silicon nitride, silicon oxynitride, silicon oxycarbonitride, etc.

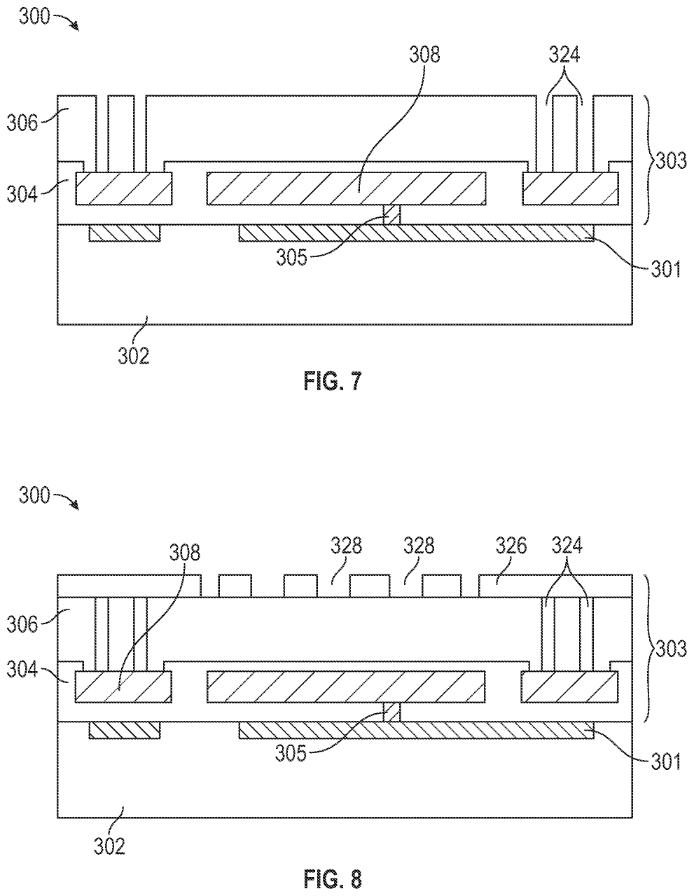

In FIG. 6, a first photoresist layer 320 can be coated on the top surface of the second dielectric layer 306 in FIG. 5. The photoresist layer 320 is then exposed to radiation of a certain wavelength projected through a mask for patterning. After development, first openings 322 can be formed in the first photoresist layer 320 to expose the second dielectric layer 306 underneath. Then the semiconductor element 300 is exposed to an etching process so that first cavities or openings 324 (into which the functional metal pads in the second dielectric layer 306 are to be provided) can be formed through the first openings 322 on the first photoresist layer 320. The cavities 324 can stop at the buried metal layer 308 as shown in the schematic cross-sectional view in FIG. 7. The first photoresist layer 320 can be stripped to expose the second dielectric layer 306 with the etched first cavities 324 therein, as shown in FIG. 7.

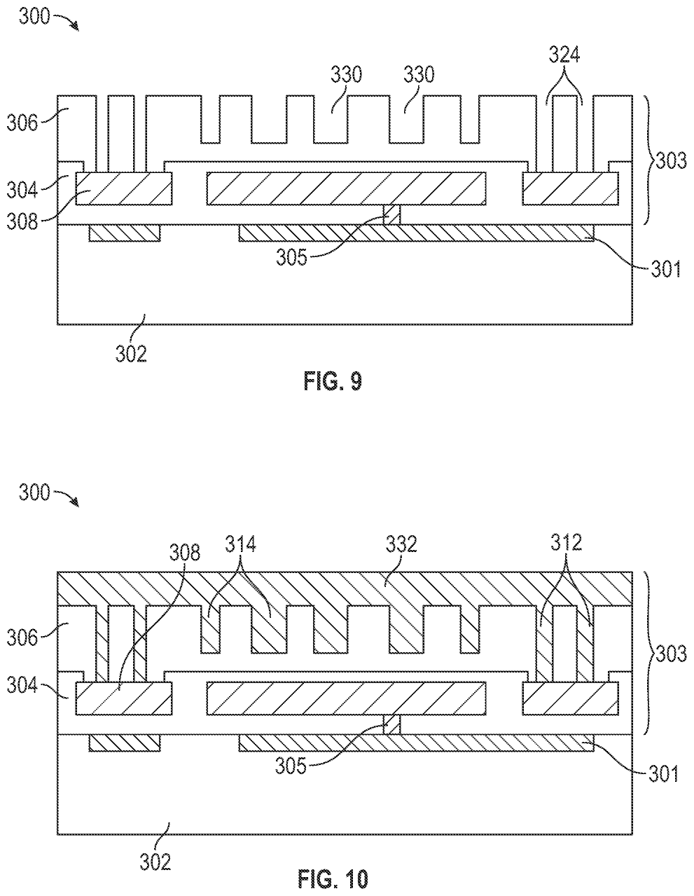

Referring to FIG. 8, a second photoresist layer 326 can be coated on the top surface of the second dielectric layer 306 and patterned. However, for the second photoresist layer 326, the second openings 328 patterned in the photoresist layer 326 are in the regions where there are no first cavities 324 for the functional metal contact pads. In other embodiments, the second openings 328 can be interspersed with the first cavities 324 in the second dielectric layer 306 depending on the density of the first cavities 324 in the area. In general, when distribution of the first cavities 324 in the second dielectric layer 306 is not uniform, the areas with sparser first cavities 324 can have more second openings 328. As with the description for FIG. 7, the second dielectric layer 306 can be etched through the second openings 328 to create second cavities or openings 330 for non-functional or dummy metal pads, as shown in FIG. 9. However, the second cavities 330 can be etched partially through the second dielectric layer 306 to terminate at a location vertically above the buried conductive layer 308. Alternatively, the second cavities 330 can be etched in any suitable manner, e.g., in an etching process of the same type for the first cavities 324 or a different type. The depth of the second cavities 330 can be controlled by timed etching, or by an etch stop layer, e.g., a silicon nitride layer. In some embodiments, the depth of the second cavities 330 in the second dielectric layer 306 can be etched to be as deep as possible but not completely through the second dielectric layer 306 (e.g., so as to not make contact with and to be disposed vertically above the conductive layer 308). In some embodiments, the second dielectric layer 306 can be formed thin such that the ratio of the depth of the second cavities 330 to the thickness of the second dielectric layer 306, which is D₃ₐ/D_{3b} shown in FIG. 3, can be, e.g., greater than 50%, 65% or 85%. When the cavities 324 and 330 are filled with metal in a future step, e.g., copper, deeper non-functional metal pads perform better for relieving stress and reducing distortion. After the second etching process, the second photoresist layer 326 is stripped to expose the top surface of the second dielectric layer 306 and the first and second cavities 324 and 330 formed therein, as shown in FIG. 9.

As explained herein, a plurality of (e.g., two) etching steps can be performed to form the functional and non-functional metal pads 312 and 314, respectively, in the semiconductor element 300 in FIG. 3. A dual damascene process also uses two etching steps, for example, to form the device of FIG. 1. However, in a dual damascene process the masking locations for the two etching steps to create the vias 110 and the functional metal pads 112 in FIG. 1 overlap. In other words, the second cavities created by the second etching step that form the trenches for the functional pads 112 are on top of the first cavities created by the first etching step that forms the vias 110. In the embodiments disclosed and discussed in connection with FIGS. 4-8, however, the first cavities 324 created by the first etching step and the second cavities 330 created by the second etching step are in different lateral locations. There is no lateral overlapping of the first and second cavities. Accordingly, each of the first cavities 324 and the second cavities 330 can be created by a single etching step, e.g., a single damascene process. Therefore, the disclosed embodiments are significantly different from the methods used to form the structure of FIG. 1.

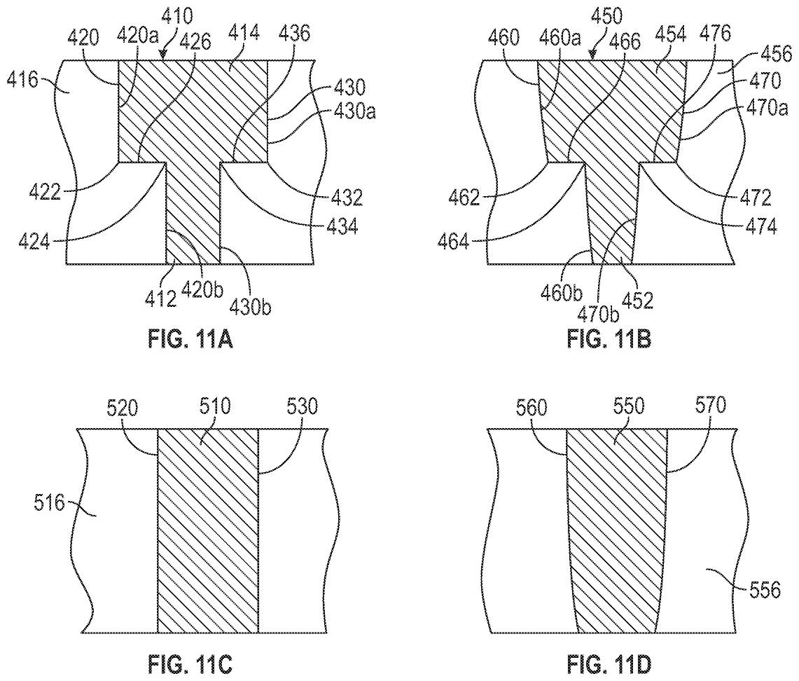

For example, one difference between the dual damascene process and the single damascene process are shown by the sidewall profiles of the holes or openings formed by the respective etch process(es), as discussed above with FIG. 1 and FIG. 2. FIGS. 11A-11B further illustrate the structures of the sidewalls formed in conjunction with the conductive features of FIG. 1, and FIGS. 11C-11D illustrate the structures of the sidewalls and pads formed in conjunction with FIGS. 2 and 3. In FIG. 11A, conductive feature 410 comprises a via portion 412 below a conductive pad portion 414, connected together and embedded in a non-conductive dielectric material 416. Such a conductive feature 410 may be formed by the dual damascene process. As can be seen in FIG. 11A the via 412 is significantly narrower in size than the conductive pad 414. Specifically, the left sidewall 420 is broken into two vertical segments, an upper segment 420a and a lower segment 420b, and a horizontal segment 426. The three line segments are joined by two corners 422 and 424, which may be approximately perpendicular or formed at another angle that produces an edge or abrupt change of direction between adjacent faces of the segments 420a, 420b, 426. As discussed above, the separation and disjointed structure of the upper pad portion 414 and the lower via portion 412 is due to the use of the dual damascene process applied to produce the conductive feature 410. The sidewall segments 420b and 430b at the lower via section portion 412 and the sidewall segments 430a and 430b at the upper pad portion 414 may be vertical or near vertical. This near vertical structure can be formed by certain etching processes, e.g., reactive-ion etching (RIE). In other embodiments, conductive features can be formed by other etching methods, e.g., wet etching and other dry etching methods.

The conductive feature 450 illustrated in FIG. 11B may be generally similar to the structure shown in FIG. 11B, except one or more of the sidewalls may be angled or curved, and segments of the sidewall may be angled at angles that are non-perpendicular. The conductive feature 450 can be formed by any suitable etching technique, including, e.g., a wet etching method. The conductive feature 450 embedded in a dielectric material 456 comprises a smaller via portion 452 and a larger conductive pad portion 454 connected together. Sidewalls 460 and 470 of the conductive feature 450 may be slightly sloped due to the etching method, forming small angles with a vertical reference line or plane. The sloped etching may be due to the upper portion of the etching channel being exposed to an etching agent for a longer period time than the lower portion. Similar to the conductive feature 410 having vertical sidewalls shown in FIG. 11A, the via portion 452 of the conductive feature 450 is significantly narrower in size than the conductive pad portion 454. Since the slope angle is small, a clear separation or discontinuity exists between the via 452 and the pad 454. Likewise, the jagged wall 460 is characterized by having two sloped segments 460a and 460b and a horizontal segment 466 joined by two corners 462 and 464. The jagged wall 470 has two sloped segments 470a and 470b and a horizontal segment 476 joined by two corners 472 and 474. In practice the corners 422, 424, 432, 434, 462, 464, 472 and 474 may not be as sharp as shown in FIG. 11A and FIG. 11B and may include a radius, but such a radius should be very small comparing to the dimensions of the sidewall segments. The clear cornered structure between the upper pad portion 454 and the lower via portion 452 is due to the dual damascene process applied to produce the conductive feature 450.

On the other hand, a conductive feature formed by the single damascene processes described herein does not have jagged or discontinuously angled sidewalls that are characteristic of conductive features formed by the dual damascene process as discussed above with FIG. 11A and FIG. 11B. In FIG. 11C, a conductive feature 510 is formed in an opening in a dielectric material 516 by a single damascene process, may be with a reactive-ion etching (RIE) method or other suitable technique. Therefore, in FIG. 11C, the sidewalls 520 and 530 of the conductive feature 510 can be vertical or substantially vertical. The structures are unitary and continuous or cornerless, without a step or discontinuity that separates an upper portion and a lower portion as shown in FIG. 11A and FIG. 11B for conductive features created by the dual damascene process. Similarly, in FIG. 11D, a conductive feature 550, formed by the single damascene process embedded in an opening in a dielectric material 556, has unitary and continuous or cornerless sidewalls 560 and 570. As compared to the vertical sidewalls 520 and 530 in FIG. 11C, sidewalls 560 and 570 may be sloped, having a slight angle with a vertical reference line or plane. The sloped sidewalls 560 and 570 maybe formed due to a wet etching method (or any other suitable material removal technique) used to create a trench to form the conductive feature 550. In some embodiments, the sloped sidewalls may have a degree of curvature but may nevertheless be continuous such that the sidewalls do not include corners. In conclusion, the conductive features 510 and 550 shown in FIG. 11C and FIG. 11D formed by the single damascene process can be formed in a simpler manner than the conductive features 410 and 450 shown in FIG. 11A and FIG. 11B formed by the dual damascene process.

Returning to FIG. 9, after the first cavities 324 for the functional or active metal pads 312 and the second cavities 330 for the non-functional metal pads 314 are formed, as shown in FIG. 9, a conductive material 332 (e.g., a metal material, e.g., copper), can be deposited (e.g., plated) to fill the first cavities 324 and the second cavities 330, so that the functional conductive pads 312 are formed in the first cavities 324 and the nonfunctional conductive pads 314 are formed in the second cavities 330, as shown in FIG. 10. In some embodiments, prior to the metal filling process of FIG. 10, a barrier layer and a metal seed layer may be deposited to cover over the entire surface of the semiconductor 300 including the cavities shown in FIG. 9.

After the metal filling process a planarization step, e.g., CMP, is applied to remove the excessive metal material to form a smooth top surface 316 of the second dielectric layer 306, as shown in FIG. 3. The planarization processes may include removing portions of any barrier layer between the metal material and the second dielectric layer 306, and maybe even portions of the second dielectric layer 306. The smooth top surface 316 of the second dielectric layer 306 can be configured to bond (e.g., directly hybrid bond) to another semiconductor element or microelectronic device. As explained below, in various embodiments, additional process(es) (such as activation and/or termination process(es)) can be performed to prepare the top surface 316 for direct bonding.

As shown in FIG. 3, the functional metal pads 312 and the non-functional metal pads 314 may have different cross-sectional dimensions because the cross-sectional dimensions of the functional metal pads 312 may be constrained by the dimensions of the metal traces 308. Density of metal pads 312 and 314 in the second dielectric layer 306 can be defined in various ways: e.g., area density, a ratio of the area of the exposed metal pads 312 and 314 to the total area of the top surface 316 as viewed in a direction perpendicular to the top surface 316, and volume density, a ratio of the volume of the metal pads 312 and 314 in the second dielectric layer 306 to the total volume of the second dielectric layer 306 including the metal pads. If the sidewalls of the metal pads 312 and 314 are formed nearly vertical, when the depth of the non-functional metal pads approaches the depth of the functional metal pads the area density can be close the volume density. Referring back to FIG. 3, the pad area density of metal pads 312 and 314 as viewed from the direction perpendicular to the to the top surface 316 of the semiconductor element 300 can be designed to be uniform or approximately uniform across the entire surface 316 to effectively control the stress due to direct bonding. In some embodiments, when a region of the surface 316 has no functional metal pads 312, non-functional metal pads 314 can be placed to match the pad density of the regions that have functional metal pads 312. In some embodiments, when a region of the surface 316 has lower pad density than other regions, non-functional metal pads 314 can be added to the region so that the pad density in the region is approximately the same as that of other regions (or otherwise is sized to balance stresses). In some embodiments, the pad area density on the surface 316 can be controlled by adjusting the size or cross-sectional dimensions of the non-functional metal pads 314. For example, smaller non-functional metal pads 314 can be placed in areas that have more functional metal pads 312, and larger non-functional metal pads 314 can be placed in areas that have less functional metal pads 312.

As shown in FIG. 3, the non-functional metal pads 314 located at a center region can be wider than non-functional pads 314 located at a peripheral region disposed about the center region. This arrangement may be used to balance the size difference of the functional metal pads 312 as viewed perpendicular to the top surface 316. Further, the ratio of the depth of the non-functional metal pads 314 to the depth of the functional metal pads 312, which is D₃ₐD_{3b}, can be made higher by forming the non-functional metal pads 314 deeper but not reaching the metal layer 308 underneath or forming the bonding layer. Because stress in the dielectric layer 306 is reduced and distortion of the semiconductor element 300 is minimized due to the placement of the non-functional metal pads 314, the surface 316 of the semiconductor 316 can be bonded to another element with reduced risk of bonding void at the interface.

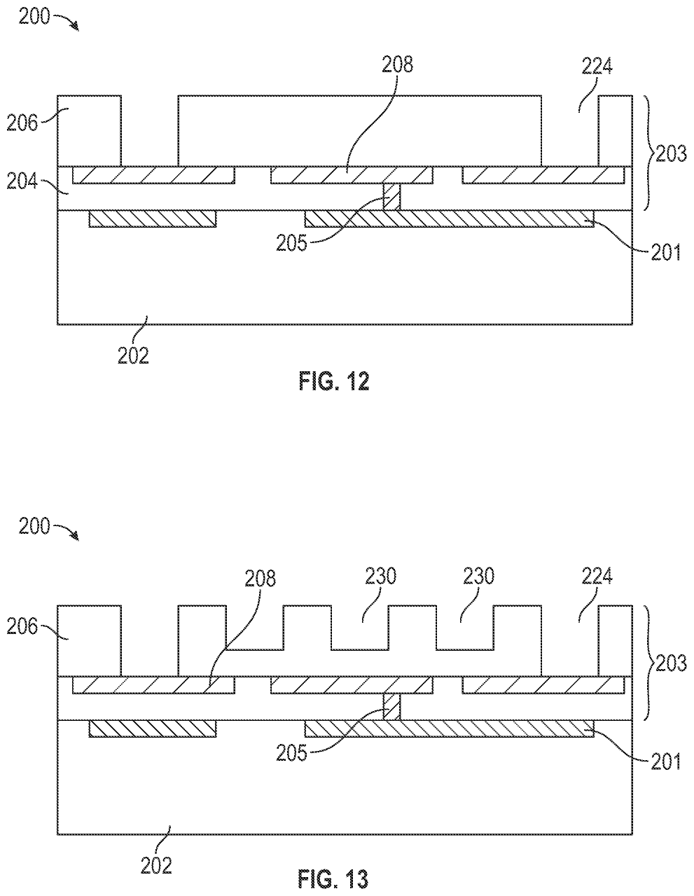

Referring now to FIG. 12 and FIG. 13, a fabrication processes of making the semiconductor element 200 shown in FIG. 2 are illustrated though schematic cross-sectional views. In FIG. 12, the semiconductor element 200 at this stage comprises the second dielectric layer 206 formed on the first dielectric layer 204 with the metal layer 208 embedded therein. The first dielectric layer 204 is disposed on the device portion 202, which has the circuitry 201 buried therein. In this embodiment, the layer of second dielectric material 206 above the metal layer may be deposited after the metal layer 208 is formed. FIG. 12 shows that first cavities 224 are formed in the second dielectric layer 206 for functional metal pads, e.g., through patterning and etching, similar to the processes described with FIGS. 6 and 7 for the semiconductor element 300. In FIG. 13, second cavities 230 are formed in the second dielectric layer 206 for non-functional metal pads, e.g., through patterning and etching, similar to the processes described with FIGS. 8 and 9 for the semiconductor element 300. Therefore, the first cavities 224 and the second cavities 230 are formed following a two-step single damascene etching process, which is significantly different from the dual damascene process used to form the semiconductor element 100 in FIG. 1. When the cavities 224 and 230 are filled with a conductive material (e.g., a metal) and planarized, similar to the process shown in FIG. 10 for semiconductor element 300, the semiconductor element 200 shown in FIG. 2 can be formed. The functional and non-functional metal pads 212 and 214, as viewed from a direction perpendicular to the top surface 216, can be distributed uniformly or approximately uniformly to minimize the stress in the dielectric layer 206. Further, the ratio of the depth of the non-functional metal pads 214 to the depth of the functional metal pads 212, which is D₂ₐ/D_{2b} as illustrated in FIG. 2, can be made higher by either forming the non-functional metal pads 214 deeper but not reaching the metal layer 208 underneath or forming the bonding layer, which includes at least part of the dielectric layer 206, thinner, in order to reduce the stress and distortion in the dielectric layer 206.

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 808a and/or 808b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements. As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

FIGS. 14 and 15 schematically illustrate cross-sectional side views of first and second elements 802, 804 prior to and after, respectively, a process for forming a directly bonded structure, and more particularly a hybrid bonded structure, according to some embodiments. In FIG. 15, a bonded structure 800 comprises the first and second elements 802 and 804 that are directly bonded to one another at a bond interface 818 without an intervening adhesive. Conductive features 806a of a first element 802 may be electrically connected to corresponding conductive features 806b of a second element 804. In the illustrated hybrid bonded structure 800, the conductive features 806a are directly bonded to the corresponding conductive features 806b without intervening solder or conductive adhesive.

The conductive features 806a and 806b of the illustrated embodiment are embedded in, and can be considered part of, a first bonding layer 808a of the first element 802 and a second bonding layer 808b of the second element 804, respectively. Field regions of the bonding layers 808a, 808b extend between and partially or fully surround the conductive features 806a, 806b. The bonding layers 808a, 808b can comprise layers of non-conductive materials suitable for direct bonding, as described above, and the field regions are directly bonded to one another without an adhesive. The non-conductive bonding layers 808a, 808b can be disposed on respective front sides 814a, 814b of base substrate portions 810a, 810b.

The first and second elements 802, 804 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 802, 804, and back-end-of-line (BEOL) interconnect layers over such semiconductor portions. The bonding layers 808a, 808b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 810a, 810b, and can electrically communicate with at least some of the conductive features 806a, 806b. Active devices and/or circuitry can be disposed at or near the front sides 814a, 814b of the base substrate portions 810a, 810b, and/or at or near opposite backsides 816a, 816b of the base substrate portions 810a, 810b. In other embodiments, the base substrate portions 810a, 810b may not include active circuitry, but may instead comprise dummy substrates, passive interposers, passive optical elements (e.g., glass substrates, gratings, lenses), etc. The bonding layers 808a, 808b are shown as being provided on the front sides of the elements, but similar bonding layers can be additionally or alternatively provided on the back sides of the elements.

In some embodiments, the base substrate portions 810a, 810b can have significantly different coefficients of thermal expansion (CTEs), and bonding elements that include such different based substrate portions can form a heterogenous bonded structure. The CTE difference between the base substrate portions 810a and 810b, and particularly between bulk semiconductor (typically single crystal) portions of the base substrate portions 810a, 810b, can be greater than 5 ppm/° C. or greater than 10 ppm/° C. For example, the CTE difference between the base substrate portions 810a and 810b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 810a, 810b can comprise optoelectronic single crystal materials, including perovskite materials, that are useful for optical piezoelectric or pyroelectric applications, and the other of the base substrate portions 810a, 810b comprises a more conventional substrate material. For example, one of the base substrate portions 810a, 810b comprises lithium tantalate (LiTaO3) or lithium niobate (LiNbO3), and the other one of the base substrate portions 810a, 810b comprises silicon (Si), quartz, fused silica glass, sapphire, or a glass. In other embodiments, one of the base substrate portions 810a, 810b comprises a III-V single semiconductor material, such as gallium arsenide (GaAs) or gallium nitride (GaN), and the other one of the base substrate portions 810a, 810b can comprise a non-III-V semiconductor material, such as silicon (Si), or can comprise other materials with similar CTE, such as quartz, fused silica glass, sapphire, or a glass. In still other embodiments, one of the base substrate portions 810a, 810b comprises a semiconductor material and the other of the base substrate portions 810a, 810b comprises a packaging material, such as a glass, organic or ceramic substrate.

In some arrangements, the first element 802 can comprise a singulated element, such as a singulated integrated device die. In other arrangements, the first element 802 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 804 can comprise a singulated element, such as a singulated integrated device die. In other arrangements, the second element 804 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 802, 804 are shown, any suitable number of elements can be stacked in the bonded structure 800. For example, a third element (not shown) can be stacked on the second element 804, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 802. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 808a, 808b, the bonding layers 808a, 808b can be prepared for direct bonding. Non-conductive bonding surfaces 812a, 812b at the upper or exterior surfaces of the bonding layers 808a, 808b can be prepared for direct bonding by polishing, for example, by chemical mechanical polishing (CMP). The roughness of the polished bonding surfaces 812a, 812b can be less than 30 Å rms. For example, the roughness of the bonding surfaces 812a and 812b can be in a range of about 0.1 Å rms to 15 Å rms, 0.5 Å rms to 10 Å rms, or 1 Å rms to 5 Å rms. Polishing can also be tuned to leave the conductive features 806a, 806b recessed relative to the field regions of the bonding layers 808a, 808b.

Preparation for direct bonding can also include cleaning and exposing one or both of the bonding surfaces 812a, 812b to a plasma and/or etchants to activate at least one of the surfaces 812a, 812b. In some embodiments, one or both of the surfaces 812a, 812b can be terminated with a species after activation or during activation (e.g., during the plasma and/or etch processes). Without being limited by theory, in some embodiments, the activation process can be performed to break chemical bonds at the bonding surface(s) 812a, 812b, and the termination process can provide additional chemical species at the bonding surface(s) 812a, 812b that alters the chemical bond and/or improves the bonding energy during direct bonding. In some embodiments, the activation and termination are provided in the same step, e.g., a plasma to activate and terminate the surface(s) 812a, 812b. In other embodiments, one or both of the bonding surfaces 812a, 812b can be terminated in a separate treatment to provide the additional species for direct bonding. In various embodiments, the terminating species can comprise nitrogen. For example, in some embodiments, the bonding surface(s) 812a, 812b can be exposed to a nitrogen-containing plasma. Other terminating species can be suitable for improving bonding energy, depending upon the materials of the bonding surfaces 812a, 812b. Further, in some embodiments, the bonding surface(s) 812a, 812b can be exposed to fluorine. For example, there may be one or multiple fluorine concentration peaks at or near a bond interface 818 between the first and second elements 802, 804. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 800, the bond interface 818 between two non-conductive materials (e.g., the bonding layers 808a, 808b) can comprise a very smooth interface with higher nitrogen (or other terminating species) content and/or fluorine concentration peaks at the bond interface 818. In some embodiments, the nitrogen and/or fluorine concentration peaks may be detected using various types of inspection techniques, such as SIMS techniques. The polished bonding surfaces 812a and 812b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 808a and 808b can be directly bonded to one another without an adhesive. In some embodiments, the elements 802, 804 are brought together at room temperature, without the need for application of a voltage, and without the need for application of external pressure or force beyond that used to initiate contact between the two elements 802, 804. Contact alone can cause direct bonding between the non-conductive surfaces of the bonding layers 808a, 808b (e.g., covalent dielectric bonding). Subsequent annealing of the bonded structure 800 can cause the conductive features 806a, 806b to directly bond.

In some embodiments, prior to direct bonding, the conductive features 806a, 806b are recessed relative to the surrounding field regions, such that a total gap between opposing contacts after dielectric bonding and prior to anneal is less than 15 nm, or less than 10 nm. Because the recess depths for the conductive features 806a and 806b can vary across each element, due to process variation, the noted gap can represent a maximum or an average gap between corresponding conductive features 806a, 806b of two joined elements (prior to anneal). Upon annealing, the conductive features 806a and 806b can expand and contact one another to form a metal-to-metal direct bond.

During annealing, the conductive features 806a, 806b (e.g., metallic material) can expand while the direct bonds between surrounding non-conductive materials of the bonding layers 808a, 808b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 806a, 806b can comprise discrete pads, contacts, electrodes, or traces at least partially embedded in the non-conductive field regions of the bonding layers 808a, 808b. In some embodiments, the conductive features 806a, 806b can comprise exposed contact surfaces of TSVs (e.g., through silicon vias).

As noted above, in some embodiments, in the elements 802, 804 of FIG. 14 prior to direct bonding, portions of the respective conductive features 806a and 806b can be recessed below the non-conductive bonding surfaces 812a and 812b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 806a, 806b or to average depths of the recesses relative to local non-conductive field regions. Even for an individual conductive feature 806a, 806b, the vertical recess can vary across the feature, and so can be measured at or near the lateral middle or center of the cavity in which a given conductive feature 806a, 806b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 806a, 806b across the direct bond interface 818 (e.g., small or fine pitches for regular arrays).

In some embodiments, a pitch p of the conductive features 806a, 806b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 806a and 806b to one of the lateral dimensions (e.g., a diameter) of the bonding pad is less than is less than 20, or less than 10, or less than 5, or less than 3 and sometimes desirably less than 2. In various embodiments, the conductive features 806a and 806b and/or traces can comprise copper or copper alloys, although other metals may be suitable, such as nickel, aluminum, or alloys thereof. The conductive features disclosed herein, such as the conductive features 806a and 806b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 802, 804, as shown, the orientations of one or more conductive features 806a, 806b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 806b in the bonding layer 808b (and/or at least one internal conductive feature, such as a BEOL feature) of the upper element 804 may be tapered or narrowed upwardly, away from the bonding surface 812b. By way of contrast, at least one conductive feature 806a in the bonding layer 808a (and/or at least one internal conductive feature, such as a BEOL feature) of the lower element 802 may be tapered or narrowed downwardly, away from the bonding surface 812a. Similarly, any bonding layers (not shown) on the backsides 816a, 816b of the elements 802, 804 may taper or narrow away from the backsides, with an opposite taper orientation relative to front side conductive features 806a, 806b of the same element.

As described above, in an anneal phase of hybrid bonding, the conductive features 806a, 806b can expand and contact one another to form a metal-to-metal direct bond. In some embodiments, the materials of the conductive features 806a, 806b of opposite elements 802, 804 can interdiffuse during the annealing process. In some embodiments, metal grains grow into each other across the bond interface 818. In some embodiments, the metal is or includes copper, which can have grains oriented along the 111 crystal plane for improved copper diffusion across the bond interface 818. In some embodiments, the conductive features 806a and 806b may include nanotwinned copper grain structure, which can aid in merging the conductive features during anneal. There is substantially no gap between the non-conductive bonding layers 808a and 808b at or near the bonded conductive features 806a and 806b. In some embodiments, a barrier layer may be provided under and/or laterally surrounding the conductive features 806a and 806b (e.g., which may include copper). In other embodiments, however, there may be no barrier layer under the conductive features 806a and 806b.

### EXAMPLES EMBODIMENTS

In various embodiments, the disclosure is a device comprising an interconnect structure having an upper surface prepared for direct bonding, a first contact pad extending to a first depth below the upper surface, and a second contact pad extending to a second depth below the upper surface, the second depth being less than the first depth.

In one aspect of the disclosure, the first contact pad comprises an active pad electrically connected to an underlying interconnect. Further, the first contact pad directly connects to the underlying interconnect without an intervening via.

In another aspect of the disclosure, the second contact pad comprises a dummy pad not electrically connected to the underlying interconnect.

In another aspect of the disclosure, the first contact pad and the second contact pad are made of metal. Further, the first contact pad and the second contact pad are made of copper.

In another aspect of the disclosure, the first contact pad is disposed in an opening having sidewalls that are continuous. Alternatively, the first contact pad is disposed in an opening having sidewalls that have no corner. The first contact pad is formed by a single damascene process.

In another aspect of the disclosure, the first pad and the second pad are approximately uniformly distributed on the upper surface of the interconnect structure. Alternatively, the first pad and the second pad are approximately uniformly distributed in the interconnect structure.

In another aspect of the disclosure, a ratio of the second depth to the first depth is greater than 50%. Alternatively, the ratio of the second depth to the first depth is greater than 85%.

In another aspect of the disclosure, the interconnect structure comprises a first dielectric layer comprises the upper surface, the first and second contact pads extending into the first dielectric layer.

In another aspect of the disclosure, the underlying interconnect is a redistribution layer (RDL) trace. Further, the underlying interconnect is an outermost metal layer of a microelectronic device.

In another aspect of the disclosure, the device further comprises a device layer, the device layer is disposed on the interconnect structure, wherein the device layer comprises circuitry electrically connected to the underlying interconnect.

In yet another aspect of the disclosure, the device layer comprises a complementary metal-oxide semiconductor (CMOS) device.

In some embodiments, the disclosure is a bonded structure comprising the device stated above and a second element comprising a second dielectric layer and a third contact pad at least partially embedded in the second dielectric layer, wherein the first dielectric layer is directly bonded to the second dielectric layer without an adhesive and the first contact pad is directly bonded to the third contact pad without an adhesive.

In some embodiments, the disclosure is a device comprising an interconnect structure having a surface prepared for direct bonding, and a plurality of pads embedded in the interconnect structure, the plurality of pads comprising a first plurality of active pads, and a second plurality of dummy pads, the dummy pads having a smaller thickness than the active pads.

In one aspect of the disclosure, each of the first plurality of active pads electrically connects to an underlying interconnect. Further, each of the first plurality of active pads directly connects to the underlying interconnect without an intervening via.

In another aspect of the disclosure, each of the second plurality of dummy pads is not electrically connected to the underlying interconnect.

In another aspect of the disclosure, the first plurality of active pads are formed by a single damascene process.

In another aspect of the disclosure, the plurality of pads are made of metal. Further, the plurality of pads are made of copper.

In another aspect of the disclosure, each active pad has sidewalls that are unitary. Alternatively, each active pad has sidewalls that have no corner.

In another aspect of the disclosure, the first plurality of active pads and the second plurality of dummy pads are approximately uniformly distributed on the surface of the interconnect structure. Alternatively, the first plurality of active pads and the second plurality of dummy pads are approximately uniformly distributed in the interconnect structure.

In another aspect of the disclosure, the surface of the interconnect structure comprises a first region having a first area density of the active pads and dummy pads with a first cross-sectional dimension and a second region having a second area density of the active pads and dummy pads with a second cross-sectional dimension, wherein the first area density is larger than the second area density, and wherein the second cross-sectional dimension is larger than the first cross-sectional dimension.

In yet another aspect of the disclosure, a ratio of the dummy pads thickness to the active pads thickness is greater than 50%. Further, the ratio of the depth is greater than 85%.

In some embodiments, the disclosure is a device comprising a device portion comprising a circuitry, an interconnect layer disposed on the device portion and having an upper bonding surface prepared for direct hybrid bonding to a second element, the interconnect layer comprising one or more non-conductive layers on the device portion, the one or more non-conductive layers having a first cavity and a second cavity formed therein, a buried conductive layer electrically connected to the circuitry and embedded in the one or more non-conductive layers at a first depth below the upper bonding surface, an electrically functional conductive pad disposed in the first cavity and extending from the upper bonding surface through at least a portion of the one or more non-conductive layers to connect to the buried conductive layer, the first cavity delimited by a continuous sidewall of the one or more non-conductive layers extending from the upper bonding surface, and an electrically non-functional conductive pad disposed in the second cavity and extending from the upper bonding surface through at least a portion of the one or more non-conductive layers, the electrically non-functional conductive pad terminating at a second depth that is less than the first depth.

In some embodiments, the disclosure is a method for fabricating a semiconductor element, comprising forming at least one first cavity in an interconnect layer of the semiconductor element, the at least one first cavity extending from an upper surface of the interconnect layer to a buried conductive layer of the semiconductor element, forming at least one second cavity in the interconnect layer laterally spaced apart from the at least one first cavity, the at least one second cavity extending from the upper surface of the interconnect layer and terminating at a depth of the dielectric layer above the buried conductive layer, providing a conductive material in the first and the second cavities, and preparing the upper surface of the interconnect layer for direct hybrid bonding to another element.

In one aspect of the disclosure, the method further comprising planarizing the upper surface by removing excessive metal material beyond the interconnect layer to form a bonding surface.

In another aspect of the disclosure, the conductive material is metal. Further, the conductive material is copper.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions, and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A device comprising:
an interconnect structure having an upper surface prepared for direct bonding;
a first contact pad extending to a first depth below the upper surface; and
a second contact pad extending to a second depth below the upper surface, the second depth being less than the first depth.

2. The device of claim 1, wherein the first contact pad comprises an active pad electrically connected to an underlying interconnect.

3. The device of claim 2, wherein the first contact pad directly connects to the underlying interconnect without an intervening via.

4. The device of claim 2, wherein the second contact pad comprises a dummy pad not electrically connected to the underlying interconnect.

5. The device of claim 1, wherein the first contact pad and the second contact pad are made of metal.

6. The device of claim 5, wherein the first contact pad and the second contact pad are made of copper.

7. (canceled)

8. The device of claim 1, wherein the first contact pad is disposed in an opening having sidewalls that have no corner.

9. (canceled)

10. The device of claim 1, wherein the first pad and the second pad are approximately uniformly distributed on the upper surface of the interconnect structure.

11. The device of claim 1, wherein the first pad and the second pad are approximately uniformly distributed in the interconnect structure.

12. The device of claim 1, wherein a ratio of the second depth to the first depth is greater than 50%.

13. The device of claim 12, wherein the ratio of the second depth to the first depth is greater than 85%.

14. The device of claim 1, wherein the interconnect structure comprises a first dielectric layer comprising the upper surface, the first and second contact pads extending into the first dielectric layer.

15. A bonded structure comprising the device of claim 14 and a second element comprising a second dielectric layer and a third contact pad at least partially embedded in the second dielectric layer, wherein the first dielectric layer is directly bonded to the second dielectric layer without an adhesive and the first contact pad is directly bonded to the third contact pad without an adhesive.

16.-19. (canceled)

20. A device comprising:
an interconnect structure having a surface prepared for direct bonding; and
a plurality of pads embedded in the interconnect structure, the plurality of pads comprising:
a first plurality of active pads; and
a second plurality of dummy pads, the dummy pads having a smaller thickness than the active pads.

21. The device of claim 20, wherein each of the first plurality of active pads electrically connects to an underlying interconnect.

22. The device of claim 21, wherein each of the first plurality of active pads directly connects to the underlying interconnect without an intervening via.

23. The device of claim 22, wherein each of the second plurality of dummy pads is not electrically connected to the underlying interconnect.

24.-26. (canceled)

27. The device of claim 20, wherein each active pad has sidewalls that are unitary.

28.-42. (canceled)

43. A device comprising:
a device portion comprising a circuitry;
an interconnect layer disposed on the device portion and having an upper bonding surface prepared for direct hybrid bonding to a second element, the interconnect layer comprising:
one or more non-conductive layers on the device portion, the one or more non-conductive layers having a first cavity and a second cavity formed therein;
a buried conductive layer electrically connected to the circuitry and embedded in the one or more non-conductive layers at a first depth below the upper bonding surface;
an electrically functional conductive pad disposed in the first cavity and extending from the upper bonding surface through at least a portion of the one or more non-conductive layers to connect to the buried conductive layer, the first cavity delimited by a continuous sidewall of the one or more non-conductive layers extending from the upper bonding surface; and
an electrically non-functional conductive pad disposed in the second cavity and extending from the upper bonding surface through at least a portion of the one or more non-conductive layers, the electrically non-functional conductive pad terminating at a second depth that is less than the first depth.

44. The device of claim 43, wherein the electrically functional conductive pad directly connects to the buried conductive layer without an intervening via.

45.-85. (canceled)
